(19) United States
(12) Patent Application Publication
(10) Pub. No.: US 2023/0416939 A1
(43) Pub. Date: Dec. 28, 2023

(54) PRODUCTION METHOD FOR AN SIC VOLUME MONOCRYSTAL OF HOMOGENEOUS SCREW DISLOCATION DISTRIBUTION AND SIC SUBSTRATE

(71) Applicant: SiCrystal GmbH, Nürnberg (DE)

(72) Inventors: Bernhard Ecker, Nürnberg (DE); Ralf Müller, Nürnberg (DE); Matthias Stockmeier, Nürnberg (DE); Michael Vogel, Nürnberg (DE); Arnd-Dietrich Weber, Nürnberg (DE)

(21) Appl. No.: 18/466,184

(22) Filed: Sep. 13, 2023

Related U.S. Application Data
(63) Continuation of application No. PCT/EP2022/056909, filed on Mar. 17, 2022.

(30) Foreign Application Priority Data
Mar. 19, 2021 (EP) 21163803.6

(51) Int. Cl. C30B 23/02; C30B 29/36; C01B 32/956

(52) U.S. Cl. CPC C30B 23/025; C30B 29/36; C01B 32/956

(57) ABSTRACT

A SiC volume monocrystal is produced by sublimation growth. An SiC seed crystal is placed in a crystal growth region of a growing crucible and SiC source material is introduced into an SiC storage region. During growth, at a growth temperature of up to 2,400° C. and a growth pressure between 0.1 mbar and 100 mbar, an SiC growth gas phase is generated by sublimation of the SiC source material and by transport of the sublimated gaseous components into the crystal growth region, where an SiC volume monocrystal grows by deposition from the SiC growth gas phase on the SiC seed crystal. Prior to the start of growth, the SiC seed crystal is examined at the growth surface for the presence of seed screw dislocations, nucleation centers are generated, wherein the nucleation centers are starting points for at least one compensation screw dislocation during the growth carried out subsequently.

### CROSS-REFERENCE TO RELATED APPLICATION

This application is a continuation of copending international patent application PCT/EP2022/056909, filed Mar. 17, 2022; the application also claims the priority of European Patent Application EP21163803.6, filed Mar. 19, 2021; the prior applications are herewith incorporated by reference in their entirety as if fully set forth herein.

### FIELD AND BACKGROUND OF THE INVENTION

The invention relates to a method for the production of at least one SiC volume monocrystal by means of sublimation growth and to a monocrystalline SiC substrate.

Due to its outstanding physical, chemical, electrical and optical properties, the semiconductor material silicon carbide (SiC) is also used, among others, as a starting material for power electronic semiconductor components, for high-frequency components and for special light-emitting semiconductor components. For these components, SiC substrates (=SiC wafers) with the largest possible substrate diameter and the highest possible quality are required.

The basis for the SiC substrates are high-grade SiC volume monocrystals, which are usually produced by means of physical vapor deposition treatment (PVT), in particular by means of a (sublimation) method described, for example, in U.S. Pat. No. 8,865,324 B2. In that growth method, a monocrystalline SiC disc is introduced into a growing crucible as an SiC seed crystal together with suitable source material. Under controlled temperature and pressure conditions, the source material is sublimed and the gaseous species deposit on the SiC seed crystal so that the SiC volume monocrystal grows there.

Disc-shaped monocrystalline SiC substrates are then cut out of the SiC volume monocrystal, e.g., with the help of a thread saw, and after a multi-stage refining treatment of their surface, in particular by means of several polishing steps, they are provided with at least one thin monocrystalline epitaxial layer, for example of SiC or GaN (gallium nitride), as part of the component manufacturing process. The properties of this epitaxial layer and thus ultimately also those of the components produced therefrom depend decisively on the quality of the SiC substrate or the underlying SiC volume monocrystal.

For the production of epitaxial layers, any threading screw dislocations (TSD) in the SiC substrate are also important, since the screw dislocations can propagate into the epitaxial layer, which can result in a reduced quality and/or yield of the electronic components produced therefrom. For a high yield, crystal defects, such as screw dislocations, which can occur during crystal growth due to deviations from the ideal crystal shape, should be avoided as far as possible. Furthermore, the production of SiC volume monocrystals by the PVT process is very cost-intensive and time-consuming. Material which is unusable for further use in the production of components, for example due to an imperfect crystal structure caused by dislocation, therefore leads to greatly reduced yields and increased costs.

A method is described in U.S. Pat. No. 9,234,297 B2 which is based on a two-stage growth process, wherein in a first growth stage at low growth rate and increased pressure, screw dislocations in the edge region of the growing SiC volume monocrystal are converted into stacking faults which then grow outwards perpendicularly to the growth direction. In the subsequent second growth stage, the growth rate is increased (at reduced pressure) and the SiC volume monocrystal growing from then on has a crystal volume with a reduced number of screw dislocations in the edge region. However, a low screw dislocation density only in the edge region is not sufficient to economically produce electronic components on SiC substrates. Therefore, further reduction of the screw dislocation density is desirable.

The process for producing a SiC volume monocrystal described in German Patent DE 10 2009 016 131 B4 comprises transferring the source material portion of the SiC source material to the crystal growth region using a SiC volume intermediate block acting as gas barrier and arranged between the storage region and the crystal growth region. A monocrystalline SiC substrate made from a such produced SiC volume monocrystal has a global dislocation density of at most 10⁴ cm⁻² and a local dislocation density of at most twice the global dislocation density. Those dislocation densities refer among others to screw dislocations.

### SUMMARY OF THE INVENTION

It is an object of the invention to provide an improved method for the production of an SiC volume monocrystal compared to known solutions, as well as an improved monocrystalline SiC substrate.

In order to achieve the object relating to the method, a method for the production of at least one SiC volume monocrystal by means of sublimation growth is disclosed, wherein prior to the start of growth an SiC seed crystal with a growth surface is arranged in a crystal growth region of a growing crucible and SiC source material, in particular in powder form or in particular compacted, preferably at least partially compacted SiC source material, or in particular SiC source material in the form of a monocrystalline or polycrystalline solid block, preferably with a density of 3.0 g/cm² to 3.21 g/cm², or in particular a combination of these different SiC source materials. During the growth, at a growth temperature of up to 2400° C., in particular at a growth interface of the growing SiC volume monocrystal, and a growth pressure between 0.1 mbar and 100 mbar by means of sublimation of the SiC source material and by means of transport of the sublimated gaseous components into the crystal growth region, an SiC growth gas phase is generated there, in which an SiC volume monocrystal grows on the SiC seed crystal by means of deposition from the SiC growth gas phase. In this process, the SiC seed crystal is examined for the presence of seed screw dislocations at the growth surface prior to the start of growth, wherein the growth surface is divided into seed segments and an associated local screw dislocation seed segment density is determined for each seed segment. Furthermore, the SiC seed crystal is treated at the growth surface before the start of growth, so that nucleation centers are generated in each seed segment whose local screw dislocation seed segment density is at least a factor of 1.5 to 4, and in particular at least a factor of 2, above a total screw dislocation seed density determined for the entire growth surface, the nucleation centers being (in particular possible) starting points for in each case at least one compensation screw dislocation during the growth carried out thereafter.

The seed segments can each be in particular round, square or rectangular and each have a seed segment area of preferably 1 mm² to 100 mm², preferably 5 mm² or 10 mm². Other seed segment geometries are also possible. Preferably, the seed segment geometries and/or the seed segment areas of all seed segments are the same. Exceptions to this may apply, for example, to the seed segments located at the edge of the SiC seed crystal. In principle, however, the seed segments can also have seed segment geometries and/or seed segment areas that otherwise deviate from one another, in particular also deviate randomly from one another.

The total screw dislocation seed density can be determined in particular by relating the number of all seed screw dislocations determined on the entire growth surface of the SiC seed crystal to the total area of this growth surface. Alternatively, the total screw dislocation seed density can also be determined as the arithmetic mean value of the local screw dislocation seed segment densities of all seed segments of the growth surface. In this respect, the total screw dislocation seed density can also be referred to as the global and/or mean screw dislocation seed density.

A screw dislocation is understood here to be both a pure screw dislocation and one of the mixed forms which also have at least one component in the m- or a-crystal direction.

Each nucleation center can, but does not have to, be an actual starting point for a compensatory screw dislocation forming during the subsequently performed crystal growth. In particular, precisely this kind of compensation screw dislocation is formed at one nucleation center. However, it is also possible that one nucleation center is the starting point for more than one compensation screw dislocation. In particular, nucleation centers are generated for all detected seed screw dislocations.

Advantageously, the nucleation centers are generated where an increased local screw dislocation seed segment density has been detected during the previous, in particular segment-by-segment, examination.

It has been recognized that a main cause for a locally increased screw dislocation density in the growing SiC volume monocrystal (and thus also in the disc-shaped SiC substrates produced therefrom subsequently) is the SiC seed crystal used for growth. Thus, seed screw dislocations prevailing in the SiC seed crystal can propagate in the growth direction into the growing SiC volume monocrystal during the growth process. In order to avoid this, the growth surface of the SiC seed crystal is treated and thereby provided with the nucleation centers that have been specifically inserted or applied. At the beginning of a growth process, these nucleation centers are in particular starting points for additional screw dislocations, namely the compensation screw dislocations. Such a compensation screw dislocation starting from a specifically placed nucleation center can then preferably recombine with the screw dislocation continuing from the SiC seed crystal at the location of the nucleation center.

Through interaction of the screw dislocations originating from the SiC seed crystal with the screw dislocations nucleated at nucleation centers, for example at their artificial surface structures (=compensation screw dislocations), these screw dislocations can recombine and be extinguished. This advantageous recombination occurs in particular when screw dislocations with different directions of rotation, i.e., with different signs of the respective Burgers vector, are involved. Since in the SiC seed crystal the ratio of the number of screw dislocations with a positive Burgers vector to the number of screw dislocations with a negative Burgers vector is usually close to 1, both proportions can be reduced in the growing SiC volume monocrystal by the deliberately induced compensation screw dislocations. This applies in particular at the positions where an increased local screw dislocation seed segment density has been detected in the SiC seed crystal during the examination, and where nucleation centers have been formed accordingly in a targeted manner.

In addition to the mechanism described above for generating compensation screw dislocations, microscopic inner surfaces can also be generated by treating, in particular structuring, the growth surface of the SiC seed crystal in connection with the incipient crystal growth process. Said microscopic inner surfaces may also be starting points for, among others, additional screw dislocations with positive or negative Burgers vectors, which can then advantageously also contribute as compensation screw dislocations to the reduction of the (increased local) screw dislocation density.

The mutually recombining screw dislocations thus preferably extinguish each other and are no longer present in the crystal structure of the growing SiC volume monocrystal from the recombination point onwards. This reduces the screw dislocation density in the growing SiC volume monocrystal, viewed both locally and globally. In addition, the distribution of the screw dislocations in the growing SiC volume monocrystal becomes uniform. The remaining screw dislocations are then distributed radially or laterally (i.e., within a cross-sectional area of the growing SiC volume monocrystal oriented perpendicularly to the growth direction; the growth direction of the growing SiC volume monocrystal, on the other hand, is also understood as an axial direction), preferably very homogeneously.

With the method according to the invention, screw dislocation density in the growing SiC volume monocrystal (and thus also in the disc-shaped SiC substrates produced therefrom subsequently) can be reduced preferably everywhere and not only, for example, in the edge region and, in particular, also be homogenized. This is an advantage over the previously known methods.

The examination and treatment of the SiC seed crystal before the start of growth is carried out in particular before the SiC seed crystal is placed in the growing crucible. During the examination, the SiC seed crystal is characterized with regard to its seed screw dislocations before it is used in the growth process. In particular, seed segments with increased local screw dislocation seed segment density are defined (=determined) and in particular also marked in order to carry out the treatment for generating the nucleation centers at the correct location. The marking is carried out in particular by using an x-y stage, which allows an exact positioning of the examined SiC seed crystal in the two lateral directions (=x- and y-direction) which are perpendicular to each other. The x-coordinate and the y-coordinate of a seed segment with increased local screw dislocation seed segment density are determined and stored.

Overall, the growth method according to the invention can be used to produce SiC volume monocrystals from which high-quality SiC substrates can be obtained. Such SiC substrates with high precision in their SiC crystal structure offer almost ideal conditions for the subsequent process steps to be carried out in the context of the production of components. SiC volume monocrystals produced according to the invention can thus be used further very efficiently, in particular for the production of semiconductor and/or high-frequency components.

The method according to the invention can be used to produce a single SiC volume monocrystal, but also a larger number, for example two, three, four, five or also preferably up to ten SiC volume monocrystals. A method in which two SiC volume monocrystals are grown, in particular arranged one above the other or one behind the other in the direction of the central longitudinal axis, which grow on both sides of the SiC storage region as viewed in the direction of the central longitudinal axis, is favorable.

Advantageous embodiments of the method according to the invention result from the features described hereinafter.

A favorable embodiment is one in which a nucleation number of nucleation centers is generated in a seed segment, in particular in each seed segment with a detected increased local screw dislocation seed segment density, which nucleation number is at least half as large as a dislocation number of seed screw dislocations determined in this seed segment. In particular, the ratio of the nucleation number to the dislocation number is in the range between 0.5 and 1. As a result, it is achieved that for as many as possible, preferably for all, of the determined seed screw dislocations, a starting point is present for a compensation screw dislocation forming in the SiC volume monocrystal later growing on the seed crystal.

According to a further favorable embodiment, the nucleation centers are generated by a locally limited, in particular additionally carried out, structuring of the growth surface. The structuring can be performed in particular by material removal and/or material application. A nucleation center and thus a possible starting point for a compensation screw dislocation can be formed very easily and very efficiently by a targeted structuring of the growth surface, such as, for example, by a locally limited generation of one or more scratches and/or by a locally limited etching. Compensation screw dislocations nucleate particularly well on such specifically generated structures of the growth surface of the SiC seed crystal, in particular at the very beginning of a growth process. Due to the structuring, the growth surface is roughened in particular at the location of the structuring. In such a structured region, the growth surface preferably has a two- to threefold higher roughness compared to unstructured regions in which no nucleation screw dislocations have been detected on the growth surface of the SiC seed crystal and in which a roughness of, in particular, Ra 0.4 nm is given. The surface roughness in regions of the growth surface of the SiC seed crystal that are specifically structured to form nucleation centers is thus set to be greater than in unstructured regions of the growth surface of the SiC seed crystal, in particular by a factor of 2 to 3.

According to a further favorable embodiment, the nucleation centers are generated by a locally limited treatment or processing of the growth surface with laser radiation. The laser radiation is usually used to structure the growth surface, in particular in a material-removing manner, but sometimes and if necessary also in a material-applying manner. By means of laser radiation, the growth surface can be very easily structured in such a manner that nucleation centers are formed.

According to a further favorable embodiment, the nucleation centers are generated by a locally limited, in particular lithographic, coating of the growth surface with an additive. By coating with the additive, in particular a material-applying structuring of the growth surface is performed. The additive used for the locally limited coating of the growth surface is at least one material from the group of carbon (C), silicon dioxide (SiO₂), graphite and graphene.

According to another favorable embodiment, the nucleation centers are generated by locally limited polishing of the growth surface. In particular, polishing is used to carry out a material-removing structuring of the growth surface. Preferably, the locally limited polishing is performed by means of a diamond suspension and/or by means of a chemo-mechanical polishing method, which is preferred. Preferably, the chemo-mechanical polishing method is performed in a defect-selective or TSD-selective manner, i.e., in particular only at those locations where a seed screw dislocation is located on the growth surface of the SiC seed crystal. During the polishing process, it is also possible, in particular, to achieve a locally higher surface roughness, for example by subsequently treating the corresponding region with a coarser-grained polishing paste (and thus roughening it again) or by using finer-grained polishing pastes for the final treatment.

According to a further favorable embodiment, the nucleation centers are generated by locally limited etching of the growth surface. In particular, the etching is used to carry out a material-removing structuring of the growth surface. The etching is also preferably carried out in a defect-selective or TSD-selective manner, i.e., in particular only at those locations where a seed screw dislocation is located on the growth surface of the SiC seed crystal.

According to yet another favorable embodiment, a nano-structure is generated on the growth surface of the SiC seed crystal to generate the nucleation centers. The generated nano-structure has in particular a geometric extension in the thickness or height direction in the range of one nanometer (1 nm) up to a few nanometers, preferably up to 10 nm, wherein in principle even thicker nano-structures are possible. The actual thickness of the nano-structure also depends in particular on the method used to produce this nano-structure.

The aforementioned embodiments for generating the nucleation centers on the growth surface of the SiC seed crystal can preferably also be combined with each other.

According to a further favorable embodiment, the examination for seed screw dislocations is performed by X-ray topography. X-ray topography is a commercially available and advantageously also non-destructive measuring method which allows the growth surface of the SiC seed crystal to be examined over the entire surface for the presence of seed screw dislocations and their distribution.

According to another favorable embodiment, the examination for seed screw dislocations and the treatment of the growth surface of the SiC seed crystal for generating the nucleation centers are performed in a combined method. In this combined method, the examination for seed screw dislocations and the treatment of the growth surface are carried out simultaneously (=in parallel). This saves time and money. In principle, however, the two method steps may also be performed sequentially, i.e., one after the other.

In order to achieve the object concerning the SiC substrate, a monocrystalline SiC substrate is disclosed which is made of a sublimation-grown SiC volume monocrystal and has a total main surface, wherein the total main surface is notionally divided into substrate segments each having an associated substrate segment area, and wherein each substrate segment has a local screw dislocation substrate segment density which indicates the number of substrate screw dislocations present in this substrate segment, and in particular detectable at the total main surface, relative to the substrate segment area of this substrate segment. Furthermore, the SiC substrate has a total screw dislocation substrate density that applies to the entire total main surface. The SiC substrate also has a sub-area formed by at least 85% of the total main surface, wherein the local screw dislocation substrate segment densities of all substrate segments located within the sub-area differ from the total screw dislocation substrate density by at most 25%.

The notional substrate segments can each be in particular round, square or rectangular and each have a substrate segment area of preferably 1 mm² to 100 mm², preferably 5 mm² or 10 mm². Other substrate segment geometries are also possible. Preferably, the substrate segment geometries and/or the substrate segment areas of all substrate segments are the same in each case. Exceptions to this may apply, for example, to the substrate segments located at the edge of the SiC substrate. In principle, however, the substrate segments can also have substrate segment geometries and/or substrate segment areas that otherwise deviate from one another, in particular also randomly deviate from one another.

The total screw dislocation substrate density can be determined in particular by relating the number of all substrate screw dislocations present and/or detectable on the total main surface of the SiC substrate to the area value of said total main surface. Alternatively, the total screw dislocation substrate density can also be determined as the arithmetic mean value of the local screw dislocation substrate segment densities of all substrate segments of the total main surface. In this respect, the total screw dislocation substrate density can also be referred to as the global and/or mean screw dislocation substrate density.

The sub-area formed by at least 85% of the total main surface can be contiguous and contain, for example, the center or the edge region. However, it may also be configured to be non-contiguous. Said sub-area advantageously has a very homogeneous distribution of substrate screw dislocations and is therefore particularly suitable for the production of electronic components.

In the context of epitaxial coating of an SiC substrate, for high-grade production of components with high yields, it is of great importance not only to have a low number of substrate screw dislocations in the SiC substrate, but also to distribute them as homogeneously as possible laterally, since the substrate screw dislocations can propagate into the epitaxial layer. For example, a high number of screw dislocations in a small space (i.e., a high local screw dislocation density) can lead to a reduction of the local charge carrier service life and to a reduction of the breakdown voltage in electronic components produced therefrom. If SiC substrates with inhomogeneous, locally increased screw dislocation densities are used, this leads to lower quality or lower yield of the electronic components manufactured therefrom. Despite these negative effects, a laterally inhomogeneous distribution of substrate screw dislocations is present in SiC substrates in known solutions, as shown for example in published patent application US 2006/0073707 A1.

In contrast, this problem does not occur with SiC substrates according to the invention. In particular, they have a low screw dislocation density and preferably also a largely homogeneous lateral distribution of the remaining substrate screw dislocations, i.e., a largely homogeneous screw dislocation distribution over the very large sub-area, and preferably also over the entire total main surface of the SiC substrate.

The SiC substrate according to the invention fulfils the industrial requirements with respect to an application for the production of semiconductor components. A substrate thickness of such an SiC substrate measured perpendicularly to the total main surface is in particular in the range between approximately 100 μm and approximately 1,000 μm and preferably in the range between approximately 200 μm and approximately 500 μm, wherein the substrate thickness has a global thickness variation of preferably at most 20 μm considered over the entire total main surface. The SiC substrate has a certain mechanical stability and is in particular self-supporting. It preferably has a substantially round disc shape, i.e., the total main surface is practically round. If applicable, there may be a slight deviation from the exactly circular geometry due to at least one identification marking provided at the peripheral edge. This identification marking may be a flat or a notch. In particular, the SiC substrate is produced from a sublimation-grown SiC volume monocrystal, for example from an SiC volume monocrystal grown according to the production method according to the invention described above, in that it has been cut as a slice perpendicular to a central longitudinal axis of the SiC volume monocrystal.

Otherwise, the SiC substrate according to the invention and its favorable variants offer essentially the same advantages that have already been described in connection with the production process according to the invention and the favorable variants thereof.

Further advantageous embodiments of the SiC substrate according to the invention result from the features disclosed hereinafter.

A favorable design is one in which the local screw dislocation substrate segment densities of all substrate segments located within the sub-area deviate from the total screw dislocation substrate density by at most 20%, in particular by at most 15%. This results in an even greater favorable homogeneity of the screw dislocation distribution.

According to a further favorable embodiment, the sub-area has a size of at least 90% of the total main surface. Thus, an even larger portion of the total main surface has an advantageous high lateral homogeneity of the screw dislocation distribution. An even larger portion of the SiC substrate can then be used for the production of high-grade components.

According to another favorable embodiment, the total screw dislocation substrate density of the SiC substrate is at most 1,000 cm⁻², in particular at most 500 cm⁻². These are very low values for the screw dislocation density, so that the SiC substrate is also very well suited for use in the production of high-grade components.

According to yet another favorable embodiment, the local screw dislocation substrate segment densities of any two substrate segments located within the sub-area and adjacent to each other differ from each other by at most 25%, in particular by at most 20% and preferably by at most 15%. Thus, adjacent substrate segments have very similar values for their respective local screw dislocation substrate segment densities. The substrate screw dislocations are thus very homogeneously distributed within the SiC substrate.

According to a further favorable embodiment, the total main surface (and thus in particular also the SiC substrate as a whole) has a substrate diameter of at least 150 mm, in particular of at least 200 mm. Preferably, the substrate diameter is approximately 200 mm. A current upper limit of the substrate diameter due to production is in particular 250 mm, wherein in principle even larger substrate diameters are conceivable. The larger the substrate diameter, the more efficiently the monocrystalline SiC substrate can be used further, for example, for the production of semiconductor and/or high-frequency components. This reduces the costs for the production of components. An SiC substrate having such a large diameter can also advantageously be used for the production of relatively large semiconductor and/or high-frequency components, which have a footprint of approximately 1 cm², for example.

According to another favorable embodiment, the SiC substrate has an SiC crystal structure with only one single SiC polytype, in particular with one of the SiC polytypes 4H, 6H, 15R and 3C. Preferably, a high modification stability is present, which is characterized in particular by the most extensive absence of polytype changes. If the SiC substrate has only one SiC polytype, it advantageously also has only a very low defect density. This results in a very high-quality SiC substrate. Polytype 4H is particularly preferred.

According to yet another favorable embodiment, the SiC substrate has a crystal structure with a slightly tilted orientation (=off-orientation) with respect to the surface normal of the total main surface, wherein a tilt angle is in the range between 0° and 8°, preferably approximately 4°. In particular, the surface normal of the total main surface corresponds at least substantially to the growth direction of the SiC volume monocrystal from which the SiC substrate is produced. In particular, in the off-orientation, the total main surface of the SiC substrate is tilted with respect to the (0001) plane of the crystal structure by an angle in the range between 0° and 8° in the direction of the [−1-120] crystal direction.

According to a further favorable embodiment, the SiC substrate has an electrical resistivity of 8 mΩcm to 26 mΩcm, in particular of 10 mΩcm to 24 mΩcm.

According to another favorable embodiment, the SiC substrate has a bow of less than 25 μm, in particular less than 15 μm.

According to yet another favorable embodiment, the SiC substrate has a warp of less than 40 μm, in particular less than 30 μm.

Further features, advantages and details of the invention will be apparent from the following description of exemplary embodiments based on the drawing.

### BRIEF DESCRIPTION OF THE FIGURES

FIG. 1 shows an exemplary embodiment of a growth arrangement for sublimation growth of an SiC volume monocrystal;

FIG. 2 shows an exemplary embodiment of an SiC seed crystal with seed screw dislocations commonly used for sublimation growth in a representation of a longitudinal section through the SiC seed crystal in the growth direction;

FIG. 3 shows an exemplary embodiment of an SiC volume monocrystal with high screw dislocation density and with inhomogeneous screw dislocation distribution, grown on the commonly used SiC seed crystal according to FIG. 2 in a longitudinal sectional representation;

FIG. 4 shows an exemplary embodiment of an SiC volume monocrystal with reduced screw dislocation density and with homogeneous screw dislocation distribution grown on an SiC seed crystal provided with nucleation centers in a targeted and locally limited manner by means of the growth arrangement according to FIG. 1 in a longitudinal sectional representation;

FIG. 5 shows the section V according to FIG. 4 with an enlarged schematic representation of a recombination of screw dislocations in the growing SiC volume monocrystal;

FIG. 6 shows an exemplary embodiment of a combined method for X-ray topographic localization of seed screw dislocations in the SiC seed crystal according to FIG. 2 and for laser structuring of the SiC seed crystal in regions with detected increased local screw dislocation density;

FIG. 7 shows an exemplary embodiment of an SiC seed crystal structured by means of local coating in regions with detected increased local screw dislocation density;

FIG. 8 shows an exemplary embodiment of an SiC substrate obtained from an SiC volume monocrystal with reduced screw dislocation density and with homogeneous screw dislocation distribution grown by means of an SiC seed crystal provided with nucleation centers in a targeted and locally limited manner, in a plan view; and

FIG. 9 shows an exemplary embodiment of an SiC substrate obtained from an SiC volume monocrystal grown by means of a commonly used SiC seed crystal according to FIG. 3 with high screw dislocation density and with inhomogeneous screw dislocation distribution, in a plan view.

### DETAILED DESCRIPTION OF THE INVENTION

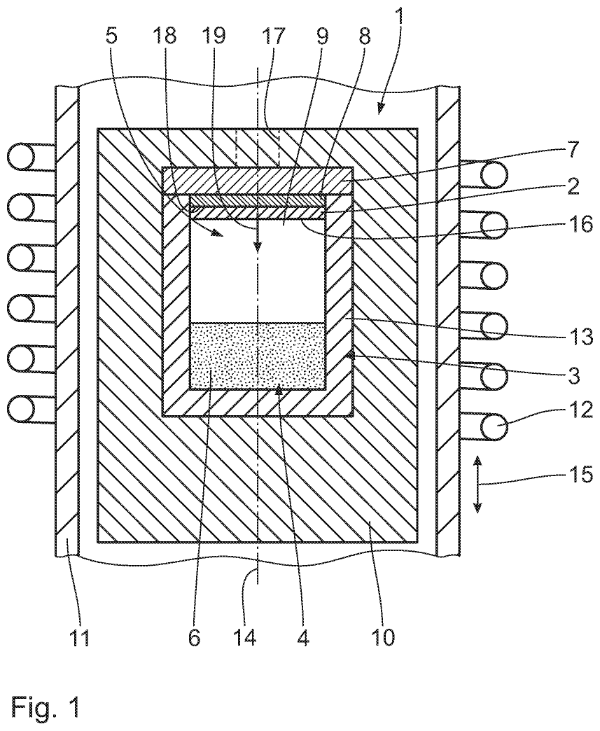

Parts that correspond to each other are marked with the same reference signs in FIGS. 1 to 9. Details of the exemplary embodiments described in more detail below may also constitute an invention in their own right or form part of a subject-matter of an invention.

FIG. 1 shows an exemplary embodiment of a growth arrangement 1 for the production of an SiC volume monocrystal 2 by means of sublimation growth. The growth arrangement 1 contains a growing crucible 3, which comprises an SiC storage region 4 and a crystal growth region 5. The SiC storage region 4 contains, for example, powdery SiC source material 6, which is filled into the SiC storage region 4 of the growing crucible 3 as a prefabricated starting material before the start of the growth process.

In the region of a crucible end wall 7 of the growing crucible 3 opposite the SiC storage region 4, an SiC seed crystal 8 extending axially into the crystal growth region 5 is attached. The SiC seed crystal 8 is in particular monocrystalline. In the exemplary embodiment shown, the crucible end wall 7 is formed as the crucible lid of the growing crucible 3. However, this is not mandatory. The SiC volume monocrystal 2 to be grown grows on the SiC seed crystal 8 by means of deposition from an SiC growth gas phase 9 forming in the crystal growth region 5. The growing SiC volume monocrystal 2 and the SiC seed crystal 8 have approximately the same diameter. If at all, there is a deviation of at most 10% by which a seed diameter of the SiC seed crystal 8 is smaller than a monocrystal diameter of the SiC volume monocrystal 2. However, a gap not shown in FIG. 1 may be present between the inner side of a crucible side wall 13 on the one hand and the growing SiC volume monocrystal 2 and the SiC seed crystal 8 on the other hand.

In the exemplary embodiment according to FIG. 1, the growing crucible 3 including the crucible lid 7 consists of an electrically and thermally conductive graphite crucible material with a density of, for example, at least 1.75 g/cm³. A thermal insulation layer 10 is arranged around it. The latter consists, for example, of a foam-like graphite insulation material whose porosity is in particular significantly higher than that of the graphite crucible material.

The thermally insulated growing crucible 3 is placed inside a tubular container 11, which in the exemplary embodiment is designed as a quartz glass tube and forms an autoclave or reactor. For heating the growing crucible 3, an inductive heating device in the form of a heating coil 12 is arranged around the container 11. The growing crucible 3 is heated to the temperatures required for growth by means of the heating coil 12. In the exemplary embodiment shown, these growth temperatures are at least 2,250° C. The heating coil 12 inductively couples an electric current into the electrically conductive crucible side wall 13 of the growing crucible 3. This electric current flows substantially as a circular current in the circumferential direction within the circular and hollow cylindrical crucible side wall 13, thereby heating the growing crucible 3. If needed, the relative position between the heating coil 12 and the growing crucible 3 can be changed axially, i.e., in the direction of a central longitudinal axis 14 of the growing SiC volume monocrystal 2, in particular in order to adjust and, if necessary, also change the temperature or the temperature profile within the growing crucible 3. The axially variable position of the heating coil 12 during the growth process is indicated in FIG. 1 by the double arrow 15. In particular, the heating coil 12 is displaced in accordance with the growth progress of the growing SiC volume monocrystal 2. The displacement preferably takes place downwards, i.e., in the direction of the SiC source material 6, and preferably by the same length by which the SiC volume monocrystal 2 grows, e.g., by a total of approximately 20 mm. For this purpose, the growth arrangement 1 comprises correspondingly designed monitoring-, control and adjustment means not shown in more detail.

The SiC growth gas phase 9 in the crystal growth region 5 is fed by the SiC source material 6. The SiC growth gas phase 9 contains at least gas components in the form of Si, Si₂C and SiC₂ (=SiC gas species). The material transport from the SiC source material 6 to a growth interface 16 at the growing SiC volume monocrystal 2 takes place on the one hand along an axial temperature gradient. In the sublimation method (=PVT method) used for SiC crystal growth, the growth conditions including the material transport are adjusted and controlled via the temperatures prevailing in the growing crucible 3. At the growth interface 16 there is a relatively high growth temperature of at least 2,250° C., in particular even of at least 2,350° C. or 2,400° C. Furthermore, an axial temperature gradient of at least 5 K/cm, preferably of at least 15 K/cm, measured in the direction of the central longitudinal axis 14, is set at the growth interface 16 in particular. The temperature within the growing crucible 3 decreases towards the growing SiC volume monocrystal 2. The highest temperature of approximately 2,450° C. to 2,550° C. prevails in the region of the SiC storage region 4. This temperature profile with a temperature difference of in particular 100° C. to 150° C. between the SiC storage region 4 and the growth interface 16 can be achieved by various measures. For example, axially varying heating can be provided by dividing the heating coil 12 into two or more axial sections, which is not shown in more detail. Furthermore, a stronger heating effect can be set in the lower section of the growing crucible 3 than in the upper section of the growing crucible 3, e.g., by a corresponding axial positioning of the heating coil 12. Moreover, the thermal insulation can be designed differently at the two axial crucible end walls. As schematically indicated in FIG. 1, the thermal insulation layer 10 can have a greater thickness at the lower crucible end wall than at the upper crucible end wall. Furthermore, it is possible that the thermal insulation layer 10 has a central cooling opening 17 arranged around the central longitudinal axis 14 adjacent to the upper crucible end wall 7, through which cooling opening 17 heat is dissipated. This central cooling opening 17 is indicated by the dashed lines in FIG. 1.

In addition, a growth pressure of in particular 0.1 hPa (=mbar) to 10 hPa (=mbar) prevails in the growing crucible 3 during the actual crystal growth.

The SiC volume monocrystal 2 grows in a growth direction 19, which in the exemplary embodiment shown in FIG. 1 is oriented from top to bottom, i.e., from the crucible lid 7 towards the SiC storage region 4. The growth direction 19 runs parallel to the centrally arranged central longitudinal axis 14. Since the growing SiC volume monocrystal 2 is arranged concentrically within the growth arrangement 1 in the exemplary embodiment shown, the centrally arranged central longitudinal axis 14 can also be assigned to the growth arrangement 1 as a whole.

The growing SiC volume monocrystal 2 has an SiC crystal structure of the 4H polytype. In principle, however, another polytype (=another crystal modification), such as 6H-SiC, 3C-SiC or 15R-SiC, is also possible. Advantageously, the SiC volume monocrystal 2 has only one SiC polytype, which in the exemplary embodiment is said 4H-SiC. The SiC volume monocrystal 2 grows with a high modification stability and in this respect has essentially only one single polytype. The latter fact is favorable with regard to a very low-defect, high crystal quality.

The growth method carried out by means of the growth arrangement 1 to produce the SiC volume monocrystal 2 is also characterized in other respects by a high crystal quality achieved. Thus, the growing SiC volume monocrystal 2 has a very low screw dislocation density and a largely homogeneous distribution of the remaining screw dislocations (TSD). In this respect, the nature of the SiC seed crystal 8 is an essential factor for the quality of the growing SiC volume monocrystal 2.

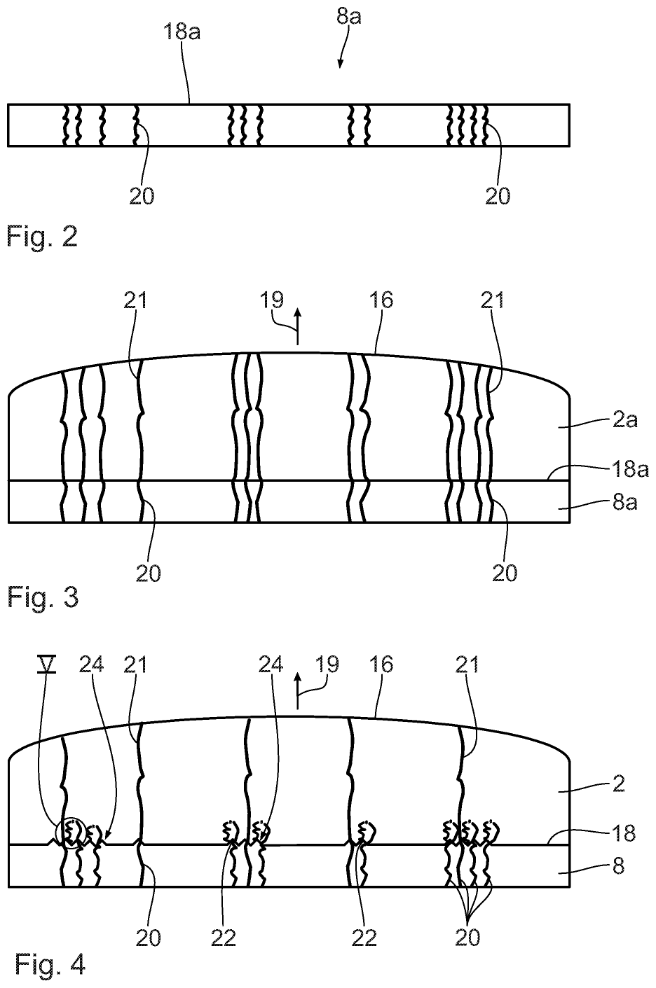

In particular, seed screw dislocations 20 (see FIG. 2) present in a commonly used SiC seed crystal 8a can propagate in the growth direction 19 into a growing SiC volume monocrystal 2a, which is illustrated in the representation according to FIG. 3. The seed screw dislocations 20 of the SiC seed crystal 8a lead to the formation of volume monocrystal screw dislocations 21 in the growing SiC volume monocrystal 2a on a growth surface 18a of the SiC seed crystal 8a that has been treated as usual, i.e., in particular completely smoothly polished. In this respect, the volume monocrystal screw dislocations 21 represent an (undesired) continuation of the seed screw dislocations 20.

To prevent the latter as far as possible, the SiC seed crystal 8 is subjected to a special two-stage treatment before it is used to grow the SiC volume monocrystal 2.

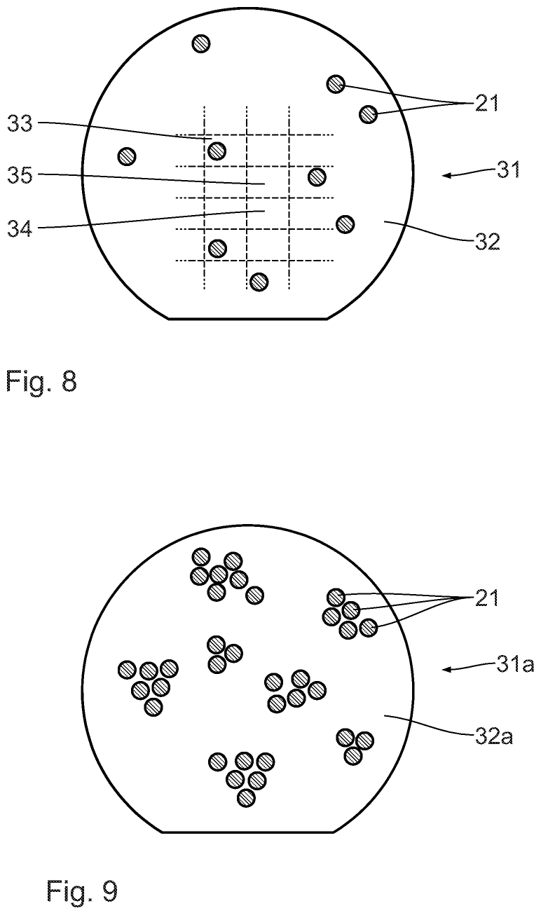

On the one hand, a seed screw dislocation examination is carried out as a first treatment stage, in the course of which a growth surface 18 of the SiC seed crystal 8 is examined segment by segment (and in particular with a segmentation comparable or similar to the segmentation schematically indicated in FIG. 8 in connection with an SiC substrate) for the presence of seed screw dislocations 20. In particular, a distribution of these seed screw dislocations 20 as well as a total screw dislocation seed density determined over the entire growth surface 18 and/or several local screw dislocation seed segment densities, each of which relates only to a specific seed segment, each approximately 10 mm² in size, of the growth surface 18, are also determined. The seed segments at which an increased local screw dislocation seed segment density has been detected can in particular be marked. A local screw dislocation seed segment density is increased if its value is at least twice as great as the value of the total screw dislocation seed segment density, i.e., is greater by at least a factor of 2.

On the other hand, a surface treatment is carried out as a second treatment stage, in the course of which the growth surface 18 is provided with nucleation centers 22 in each case in the region of seed segments with a detected increased local screw dislocation seed segment density.

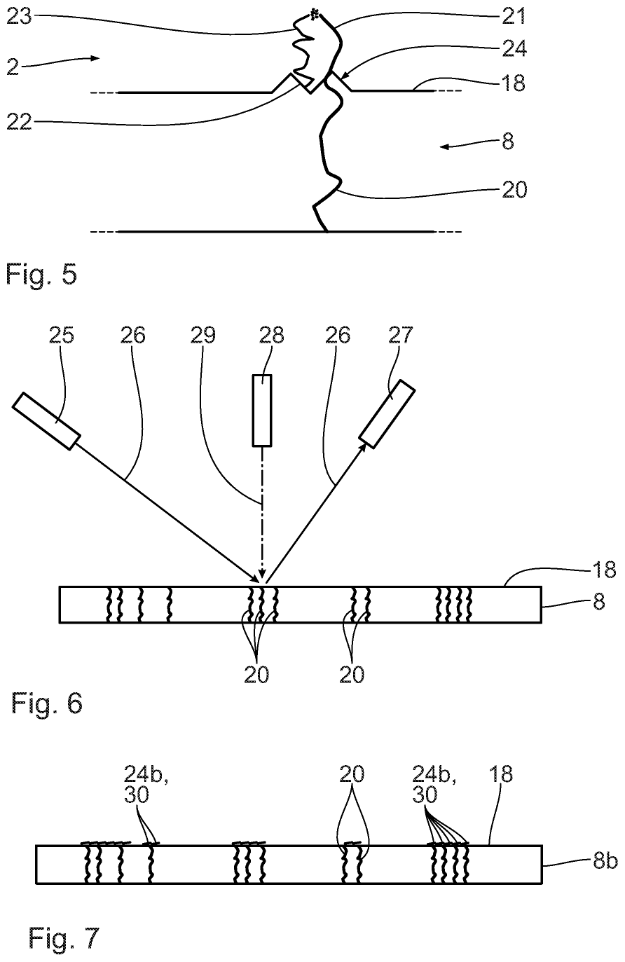

Each of these nucleation centers 22 can serve as the starting point of a compensation screw dislocation 23 during the actual sublimation growth of the SiC volume monocrystal 2. Such a compensation screw dislocation 23 starting from a specifically placed nucleation center 22 during the actual sublimation growth can recombine with the volume monocrystal screw dislocation 21 continuing from the SiC seed crystal 8 at the location of the nucleation center 22 (see FIG. 4 as well as enlarged detailed representation according to FIG. 5). The volume monocrystal screw dislocation 21 originating from the SiC seed crystal 8 and actually continuing in the SiC volume monocrystal 2 and the compensation screw dislocation 23 advantageously cancel each other out. This results in a reduction of the screw dislocation density in the growing SiC volume monocrystal 2—and also in disc-shaped monocrystalline SiC substrates 31 produced therefrom for the production of components (see FIG. 8)—as well as a homogenization of the distribution of the remaining volume monocrystal screw dislocation 21.

The generation of the favorable nucleation centers 22 is performed by a locally limited structuring of the growth surface 18, in particular in the seed segments with detected increased local screw dislocation seed segment density. The growth surface 18 is provided in a targeted and locally limited manner with nucleation structures 24, which are designed as roughened surface regions according to the exemplary embodiment shown in FIGS. 4 and 5. However, other designs of the nucleation structures 24 are also possible, for example locally limited polished, etched and/or coated surface regions. The nucleation structures 24 shown in FIGS. 4 and 5 in the form of roughened surface regions on the growth surface 18 of the SiC seed crystal 8 can be produced, for example, by means of laser radiation.

It has been shown that a locally limited structuring of the growth surface 18 leads to significantly better results with regard to the desired reduction of the screw dislocation density and homogenization of the screw dislocation distribution in the growing SiC volume monocrystal 2 than with a continuous structuring of the growth surface 18.

The seed screw dislocation examination as the first treatment stage and the surface treatment as the second treatment stage can basically be performed one after the other and, if necessary, also using separate facilities. However, the exemplary embodiment shown in FIG. 6 of a combined and, in particular, simultaneous execution of these two treatment stages is particularly efficient. Here, the seed screw dislocation examination is carried out X-ray topographically. An X-ray source 25 emits X-ray radiation 26 in the direction of the growth surface 18 and successively and in particular completely scans the growth surface 18 with this X-ray radiation 26. An X-ray detector 27 receives the X-ray radiation 26 reflected from the growth surface 18 and converts it into a received signal, which is then fed to an evaluation unit (not shown) for further evaluation of whether a seed screw dislocation 20 is provided at the current reflection point of the X-ray radiation 26 on the growth surface 18. If this evaluation shows that there is a relevant increased local screw dislocation seed segment density in the seed segment just examined, a laser writer 28 is triggered and caused to treat this seed segment of the growth surface 18 by means of laser radiation 29 and to generate a nucleation structure 24 with nucleation centers 22 there.

In FIG. 7, an exemplary embodiment of an SiC seed crystal 8b with other nucleation structures 24b on its growth surface 18b is shown. The latter are also locally limited and placed in seed segments of the growth surface 18b with detected increased local screw dislocation seed segment density. To generate these nucleation structures 24b, the growth surface 18b is lithographically nano-structured in the relevant seed segments, in the exemplary embodiment according to FIG. 7 provided with a carbon coating 30.

The growth arrangement 1, when using one of the SiC seed crystals 8, 8b with suitable locally limited surface structuring, enables the growth of a high-grade SiC volume monocrystal 2 which has only a few volume monocrystal screw dislocations 21 and which has a very homogeneous lateral distribution.

From these high-grade SiC volume monocrystals 2, equally high-grade SiC substrates 31 (see schematic representation according to FIG. 8) can then be produced. These disc-shaped SiC substrates 31 are obtained from the SiC volume monocrystal 2 in question by cutting or sawing them off axially successively as discs perpendicular to the growth direction 19 or to the central longitudinal axis 14. Such an SiC substrate 31 is large and thin. In one possible embodiment, its total main surface 32 has a substrate diameter of at least 150 mm, for example 200 mm, whereas a substrate thickness is approximately 500 μm. The SiC substrate 31, like the SiC volume monocrystal 2 from which it is made, has a low total screw dislocation density of preferably at most 1,000 cm⁻² and a very homogeneous distribution of the remaining volume monocrystal screw dislocations 21, both of which improve the suitability of the SiC substrate 31 for use in the production of components. The total screw dislocation density refers to a complete cross-sectional area of the SiC volume monocrystal 2 perpendicular to the central longitudinal axis 14 or to the growth direction 19 in the case of the SiC volume monocrystal 2 and to the complete total main surface 32 in the case of the SiC substrate 31. In the case of the SiC substrate 31, it is also referred to herein as the total screw dislocation substrate density. The very homogeneous screw dislocation distribution can be seen in the illustration according to FIG. 8, in which the Si side of the SiC substrate 31 is shown.

In FIG. 8, a (notional) division of the total main surface 32 into substrate segments 33 is also illustrated by dashed lines, wherein the substrate segments 33, at least insofar as they have no reference to the substrate edge, are each square and have a substrate segment area of in particular 10 mm². Each substrate segment 33 has a local screw dislocation substrate segment density which indicates the number of volume monocrystal screw dislocations 21 present therein relative to its substrate segment area. With respect to the SiC substrate 31, the volume monocrystal screw dislocations 21 may also be understood and referred to as substrate screw dislocations 21. Within an 85% sub-area of the total major surface 32, the substrate segments 33 have a local screw dislocation substrate segment density which deviates from the total screw dislocation substrate density by at most 25% in each case. The few substrate screw dislocations 21 are therefore also very homogeneously distributed. The latter is additionally also achieved by the fact that any adjacent substrate segments 34 and 35 within this sub-area differ from each other in their respective local screw dislocation substrate segment densities by at most 25%.

For the sake of comparison, FIG. 9 also shows the Si side of a commonly used SiC substrate 31a, which is made of an SiC volume monocrystal 2a grown by means of a commonly used SiC seed crystal 8a without locally limited surface structuring (see FIG. 3). The higher total screw dislocation density as well as the more inhomogeneous screw dislocation distribution over the total main surface 32a can be seen in the schematic representation according to FIG. 9.

1. A method of producing at least one SiC volume monocrystal by sublimation growth, the method comprising:
a) prior to a start of the growth:
a1) arranging an SiC seed crystal having a growth surface in a crystal growth region of a growing crucible; and
a2) introducing an SiC source material into an SiC storage region of the growing crucible; and
b) during the growth at a growth temperature of up to 2400° C. and a growth pressure between 0.1 mbar and 100 mbar by way of a sublimation of the SiC source material and by way of a transport of sublimated gaseous components into the crystal growth region, producing an SiC growth gas phase in the crystal growth region, in which the SiC volume monocrystal grows on the SiC seed crystal by deposition from the SiC growth gas phase; and
c) prior to the start of the growth on the growth surface:
c1) examining the SiC seed crystal for a presence of seed screw dislocations by dividing the growth surface into seed segments and determining an associated local screw dislocation seed segment density for each seed segment; and
c2) treating the SiC seed crystal to generate nucleation centers in each seed segment whose local screw dislocation seed segment density is at least a factor of 1.5 to 4 above a total screw dislocation seed density determined for the entire growth surface, wherein the nucleation centers are respective starting points for at least one compensation screw dislocation during the growth that is subsequently carried out.

2. The method according to claim 1, which comprises, in a seed segment with a detected increased local screw dislocation seed segment density, generating a nucleation number of nucleation centers which is at least half as large as a dislocation number of seed screw dislocations determined in the respective seed segment.

3. The method according to claim 1, which comprises generating the nucleation centers by a locally limited structuring of the growth surface.

4. The method according to claim 1, which comprises generating the nucleation centers by a locally limited treatment of the growth surface with laser radiation.

5. The method according to claim 1, which comprises generating the nucleation centers by a locally limited coating of the growth surface with an additive.

6. The method according to claim 1, which comprises generating the nucleation centers by a locally limited polishing of the growth surface.

7. The method according to claim 1, which comprises generating the nucleation centers by a locally limited etching of the growth surface.

8. The method according to claim 1, which comprises producing at least one nano-structure for generating the nucleation centers at the growth surface of the SiC seed crystal.

9. The method according to claim 1, wherein the step of examining the SiC seed crystal for seed screw dislocations is performed by X-ray topography.

10. The method according to claim 1, which comprises performing the steps of examining for seed screw dislocations and treating the growth surface of the SiC seed crystal to generate the nucleation centers in a combined method.

11. A monocrystalline SiC substrate produced from a sublimation-grown SiC volume monocrystal, the SiC substrate comprising:
a) a total main surface being notionally divided into substrate segments each having an associated substrate segment area, with each of said substrate segments having a local screw dislocation substrate segment density which indicates a number of substrate screw dislocations present in the respective substrate segment relative to the associated substrate segment area of said substrate segment;
b) a total screw dislocation substrate density that is applicable to the total main surface of the SiC substrate as a whole; and
c) a sub-area that is formed by at least 85% of the total main surface, wherein the local screw dislocation substrate segment densities of all substrate segments lying within said sub-area deviate from the total screw dislocation substrate density by at most 25%.

12. The SiC substrate according to claim 11, wherein the local screw dislocation substrate segment densities of all substrate segments lying within the sub-area deviate from the total screw dislocation substrate density by at most 20%.

13. The SiC substrate according to claim 11, wherein the local screw dislocation substrate segment densities of all substrate segments lying within the sub-area deviate from the total screw dislocation substrate density by at most 15%.

14. The SiC substrate according to claim 11, wherein said sub-area has a size of at least 90% of the total main surface.

15. The SiC substrate according to claim 11, wherein the total screw dislocation substrate density of the SiC substrate is at most 1,000 cm⁻².

16. The SiC substrate according to claim 11, wherein the total screw dislocation substrate density of the SiC substrate is at most 500 cm⁻².

17. The SiC substrate according to claim 11, wherein the screw dislocation substrate segment densities of any two substrate segments that are located within said sub-area and are adjacent to each other differ from each other by at most 25%.

18. The SiC substrate according to claim 11, wherein the screw dislocation substrate segment densities of any two substrate segments that are located within the sub-area and are adjacent to each other differ from each other by at most 20%.

19. The SiC substrate according to claim 11, wherein the screw dislocation substrate segment densities of any two substrate segments that are located within said sub-area and are adjacent to each other differ from each other by at most 15%.

20. A method of producing an SiC volume monocrystal by sublimation growth, the method comprising:
providing an SiC seed crystal having a growth surface;
examining the SiC seed crystal for a presence of seed screw dislocations by dividing the growth surface into seed segments and determining an associated local screw dislocation seed segment density for each seed segment;
treating the SiC seed crystal to generate nucleation centers in each seed segment whose local screw dislocation seed segment density is at least a factor of 1.5 to 4 above a total screw dislocation seed density determined for the entire growth surface, the nucleation centers being starting points for compensation screw dislocations to be formed during a subsequent growth;
arranging the SiC seed crystal in a crystal growth region of a growing crucible;
introducing an SiC source material into an SiC storage region of the growing crucible; and
setting a growth temperature of up to 2400° C. and a growth pressure between 0.1 mbar and 100 mbar, sublimating the SiC source material and transporting sublimated gaseous components into the crystal growth region for producing an SiC growth gas phase in the crystal growth region, and growing the SiC volume monocrystal on the SiC seed crystal by deposition from the SiC growth gas phase.
